(19) United States
(12) Patent Application Publication
(10) Pub. No.: US 2025/0048542 A1
(43) Pub. Date: Feb. 6, 2025

(54) CIRCUIT MODULE AND MANUFACTURING METHOD THEREFOR

(71) Applicant: Murata Manufacturing Co., Ltd., Nagaokakyo-shi (JP)

(72) Inventors: Nobuo IKEMOTO, Nagaokakyo-shi (JP); Eiichi TAKATA, Nagaokakyo-shi (JP); Kazuhiro YAMAJI, Nagaokakyo-shi (JP); Hideki UEDA, Nagaokakyo-shi (JP)

(21) Appl. No.: 18/925,509

(22) Filed: Oct. 24, 2024

Related U.S. Application Data
(63) Continuation of application No. PCT/JP2023/018518, filed on May 18, 2023.

(30) Foreign Application Priority Data
Jun. 23, 2022 (JP) 2022-100831

(51) Int. Cl. H05K 1/02; H05K 1/03; H05K 1/11; H05K 1/18; H05K 3/00; H05K 3/42

(52) U.S. Cl. CPC H05K 1/0271; H05K 1/0313; H05K 1/115; H05K 1/181; H05K 3/0094; H05K 3/429; H05K 2201/10287; H05K 2201/10689; H05K 2201/10909; H05K 2203/049

(57) ABSTRACT

In a circuit module, a mounting electrode is located on a positive main surface of a resin layer positioned farther toward a positive side of a Z axis than other resin layers. An inner conductive layer overlaps the mounting electrode. An end of a first interlayer connection conductor on the positive side contacts the mounting electrode. An end of the first interlayer connection conductor on a negative side of the Z axis contacts the inner conductive layer. A product includes a connector bonded to the mounting electrode. The first interlayer connection conductor includes first and second regions provided in a direction toward the negative side in this order. A material of the first region is the same as that of the mounting electrode. A Young's modulus of the second region is lower than that of the first region.

### CROSS REFERENCE TO RELATED APPLICATIONS

This application claims the benefit of priority to Japanese Patent Application No. 2022-100831 filed on Jun. 23, 2022 and is a Continuation Application of PCT Application No. PCT/JP2023/018518 filed on May 18, 2023. The entire contents of each application are hereby incorporated herein by reference.

### BACKGROUND OF THE INVENTION

### 1. Field of the Invention

The present invention relates to circuit modules each including a product and a circuit substrate.

### 2. Description of the Related Art

As an invention of a circuit module of the related art, a semiconductor device disclosed in Japanese Unexamined Patent Application Publication No. 2008-243884, for example, is known. The semiconductor device includes an IC chip and a multilayer wiring substrate. Plural IC connection terminals are provided on the top main surface of the multilayer wiring substrate. Plural via connection terminals and plural support vias are provided within the multilayer wiring substrate. Each of the support vias connects a corresponding IC connection terminal and a corresponding via connection terminal with each other.

The IC chip includes plural solder bumps. The solder bumps are bonded to the corresponding IC connection terminals.

In the field of semiconductor devices such as that disclosed in Japanese Unexamined Patent Application Publication No. 2008-243884, an ultrasonic bonding technology may be used to bond plural solder bumps and plural IC connection terminals to each other. In this case, ultrasonic vibrations are transmitted to the IC connection terminals and support vias and are thus applied to the boundaries between the support vias and via connection terminals, which may cause damage to the connecting portions therebetween.

### SUMMARY OF THE INVENTION

Example embodiments of the present invention provide circuit modules and manufacturing methods therefor that each reduce or prevent damage to a connecting portion between an interlayer connection conductor and an inner conductive layer.

A circuit module according to an example embodiment of the present invention includes a circuit substrate and a product. The circuit substrate includes a multilayer body, a mounting electrode, an inner conductive layer, and a first interlayer connection conductor. The multilayer body includes a plurality of resin layers stacked on each other in a direction of a Z axis. Each of the plurality of resin layers includes a positive main surface positioned on a positive side of the Z axis. The mounting electrode is provided on the positive main surface of a resin layer which is positioned farther toward the positive side of the Z axis than other resin layers of the plurality of resin layers. The inner conductive layer is provided in the multilayer body and overlaps the mounting electrode as seen in the direction of the Z axis. The first interlayer connection conductor extends through a resin layer of the plurality of resin layers in the direction of the Z axis. An end of the first interlayer connection conductor on the positive side of the Z axis contacts the mounting electrode, and an end of the first interlayer connection conductor on a negative side of the Z axis contacts the inner conductive layer. The product includes a connector solid-phase bonded to the mounting electrode. The first interlayer connection conductor includes a first region and a second region. The first region and the second region are sequentially provided in a direction toward the negative side of the Z axis in order of the first region and the second region. A Young's modulus of the second region is lower than a Young's modulus of the first region.

A circuit module according to an example embodiment of the present invention includes a circuit substrate and a product. The circuit substrate includes a multilayer body, a mounting electrode, an inner conductive layer, a third interlayer connection conductor, and a fourth interlayer connection conductor. The multilayer body includes a plurality of resin layers stacked on each other in a direction of a Z axis. Each of the plurality of resin layers includes a positive main surface positioned on a positive side of the Z axis. The mounting electrode is provided on the positive main surface of a resin layer which is positioned farther toward the positive side of the Z axis than other resin layers of the plurality of resin layers. The inner conductive layer is provided in the multilayer body and overlaps the mounting electrode as seen in the direction of the Z axis. The third interlayer connection conductor extends through a resin layer of the plurality of resin layers in the direction of the Z axis. An end of the third interlayer connection conductor on the positive side of the Z axis contacts the mounting electrode, and an end of the third interlayer connection conductor on a negative side of the Z axis contacts the inner conductive layer. The fourth interlayer connection conductor extends through a resin layer of the plurality of resin layers in the direction of the Z axis and overlaps the mounting electrode as seen in the direction of the Z axis. An end of the fourth interlayer connection conductor on the positive side of the Z axis contacts the inner conductive layer. The product includes a connector solid-phase bonded to the mounting electrode. The fourth interlayer connection conductor includes a third region and a fourth region provided in the direction of the Z axis. A material of the third interlayer connection conductor and a material of the third region are the same as a material of the mounting electrode. A Young's modulus of the fourth region is lower than a Young's modulus of the third region.

Circuit modules according to example embodiments of the present invention are able to reduce or prevent damage to a connecting portion between an interlayer connection conductor and an inner conductive layer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a sectional view of a circuit module 10 according to an example embodiment of the present invention.

FIG. 2 is a sectional view of a circuit module 10a according to an example embodiment of the present invention.

FIG. 3 is a sectional view of a circuit module 10b according to an example embodiment of the present invention.

FIG. 4 is a sectional view of a circuit module 10c according to an example embodiment of the present invention.

### DETAILED DESCRIPTION OF THE EXAMPLE EMBODIMENTS

### Example Embodiments

### Structure of Circuit Module

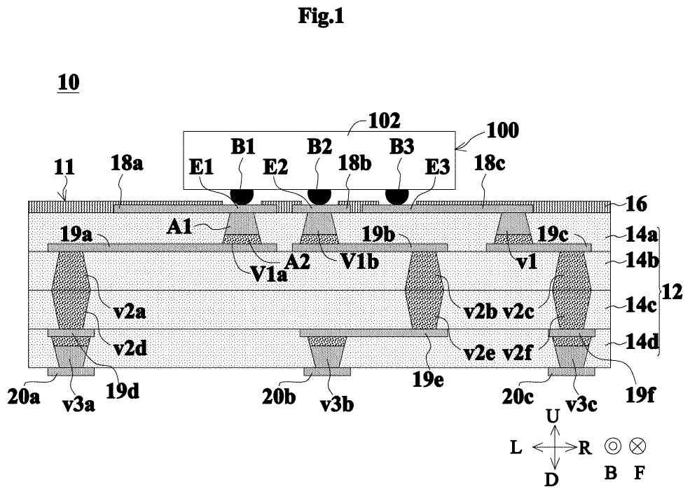

The structure of a circuit module 10 according to an example embodiment of the present invention will be described below with reference to the drawing. FIG. 1 is a sectional view of the circuit module 10.

In the specification, the directions are defined as follows. The stacking direction of layers of a multilayer body 12 is defined as an up-down direction. The up-down direction coincides with the Z-axis direction. The up direction is a direction toward the positive side of the Z axis. The down direction is a direction toward the negative side of the Z axis. Directions perpendicular to the up-down direction are defined as a left-right direction and a front-back direction. The left-right direction is perpendicular to the front-back direction. The up direction and the down direction of the up-down direction may be replaced by each other. The left direction and the right direction of the left-right direction may be replaced by each other. The front direction and the back direction of the front-back direction may be replaced by each other.

The circuit module 10 is used for a wireless communication terminal, such as a smartphone, for example. The circuit module 10 includes a circuit substrate 11 and a product 100.

The circuit substrate 11 transfers a radio-frequency signal therethrough. The circuit substrate 11 includes a multilayer body 12, a protection layer 16, conductive layers 18a through 18c and 20a through 20c, inner conductive layers 19a through 19f, first interlayer connection conductors V1a and V1b, interlayer connection conductors v1 and v3a through v3c, and second interlayer connection conductors v2a through v2f.

The multilayer body 12 has a planar shape including a top main surface and a bottom main surface. The structure of the multilayer body 12 is such that resin layers 14a through 14d each including a top main surface (positive surface on the positive side of the Z axis) and a bottom main surface are stacked on each other in the up-down direction (Z-axis direction). The resin layers 14a through 14d are arranged from top to bottom in this order. The resin layers 14a through 14d have a rectangular or substantially rectangular shape as seen in the up-down direction. The material of the resin layers 14a through 14d is a resin, such as a thermoplastic resin, for example. The thermoplastic resin is a liquid crystal polymer, for example. The multilayer body 12 thus has flexibility.

The conductive layers 18a through 18c are disposed on the multilayer body 12. The conductive layers 18a through 18c are positioned on the top main surface (positive main surface) of the resin layer 14a, which is located at the uppermost position among the resin layers 14a through 14d (farther toward the positive side of the Z axis than the resin layers 14b through 14d). The conductive layers 18a through 18c include mounting electrodes E1 through E3, respectively. The mounting electrodes E1 through E3 are thus positioned on the top main surface (positive main surface) of the resin layer 14a, which is located at the uppermost position among the resin layers 14a through 14d (farther toward the positive side of the Z axis than the resin layers 14b through 14d). The mounting electrodes E1 through E3 are the portions of the conductive layers 18a through 18c that are not covered by the protection layer 16, which will be discussed later. The mounting electrodes E1 through E3 each have a rectangular or substantially rectangular shape as seen in the up-down direction.

The conductive layers 18a through 18c are arranged from left to right in this order. The conductive layer 18a extends in the left-right direction. The mounting electrode E1 is positioned at the right end portion of the conductive layer 18a. The conductive layer 18b has a square or substantially square shape. The mounting electrode E2 is located at the center or approximate center of the conductive layer 18b. The conductive layer 18c extends in the left-right direction. The mounting electrode E3 is positioned at the left end portion of the conductive layer 18c.

The inner conductive layers 19a through 19c are disposed in the multilayer body 12. The inner conductive layers 19a through 19c are located on the top main surface of the resin layer 14b. The inner conductive layers 19a through 19c are arranged from left to right in this order. The inner conductive layers 19a through 19c extend in the left-right direction. The inner conductive layers 19a and 19b overlap the mounting electrodes E1 and E2, respectively, as seen in the up-down direction (Z-axis direction). In the present example embodiment, the right end portion of the inner conductive layer 19a overlaps the mounting electrode E1 as seen in the up-down direction, while the left end portion of the inner conductive layer 19b overlaps the mounting electrode E2 as seen in the up-down direction.

The inner conductive layers 19d through 19f are disposed in the multilayer body 12. The inner conductive layers 19d through 19f are located on the bottom main surface of the resin layer 14c. The inner conductive layers 19d through 19f are arranged from left to right in this order.

The conductive layers 20a through 20c are disposed on the multilayer body 12. The conductive layers 20a through 20c are located on the bottom main surface of the resin layer 14d. The conductive layers 20a through 20c are arranged from left to right in this order. The conductive layers 20a through 20c each have a rectangular or substantially rectangular shape as seen in the up-down direction. The conductive layers 20a through 20c are outer electrodes, for example.

The above-described conductive layers 18a through 18c and 20a through 20c and inner conductive layers 19a through 19f are formed, for example, by patterning of a metal foil attached to the top main surfaces of the resin layers 14a and 14b and to the bottom main surfaces of the resin layers 14c and 14d. The metal foil is a copper foil, for example.

The mounting electrodes E1 through E3 are formed by, for example, plating the surface of a copper foil with nickel and gold. The material for the surface of the mounting electrodes E1 through E3 is, for example, gold.

The protection layer 16 covers the entirety or substantially the entirety of the positive main surface (top main surface) of the resin layer 14a located at the uppermost position among the resin layers 14a through 14d (farther toward the positive side of the Z axis than the resin layers 14b through 14d). The protection layer 16 protects the conductive layers 18a through 18c in this manner. The mounting electrodes E1 through E3 are not covered by the protection layer 16. The protection layer 16 is not a portion of the multilayer body 12. No conductive layer is provided on the top main surface of the protection layer 16.

The first interlayer connection conductors V1a and V1b are provided in the multilayer body 12. In the present example embodiment, the first interlayer connection conductors V1a and V1b extend through the resin layer 14a in the up-down direction (Z-axis direction). The first interlayer connection conductor V1a overlaps the mounting electrode E1 and the right end portion of the inner conductive layer 19a as seen in the up-down direction. The top end (end of the positive side of the Z axis) of the first interlayer connection conductor V1a thus contacts the mounting electrode E1. The bottom end (end of the negative side of the Z axis) of the first interlayer connection conductor V1a thus contacts the inner conductive layer 19a. The first interlayer connection conductor V1b overlaps the mounting electrode E2 and the left end portion of the inner conductive layer 19b as seen in the up-down direction. The top end (end of the positive side of the Z axis) of the first interlayer connection conductor V1b thus contacts the mounting electrode E2. The bottom end (end of the negative side of the Z axis) of the first interlayer connection conductor V1b thus contacts the inner conductive layer 19b.

The shape of the first interlayer connection conductors V1a and V1b is such that the sectional area of each of the first interlayer connection conductors V1a and V1b in a direction perpendicular or substantially perpendicular to the up-down direction becomes smaller in a direction from bottom to top. More specifically, the first interlayer connection conductors V1a and V1b have a shape of a truncated cone. The area of the top end of each of the first interlayer connection conductors V1a and V1b is smaller than that of the bottom end thereof.

The first interlayer connection conductors V1a and V1b each include a first region A1 and a second region A2. The first region A1 and the second region A2 are arranged in a downward direction (toward the negative side of the Z axis) in this order. The second region A2 is thus positioned below the first region A1 (farther toward the negative side of the Z axis than the first region A1). The volume of the first region A1 is, for example, about 30% or higher of that of the corresponding one of the first interlayer connection conductors V1a and V1b. The Young's modulus of the second region A2 is lower than that of the first region A1. The Young's modulus of the lower half of each of the first interlayer connection conductors V1a and V1b is thus different from that of the upper half thereof. The heat transfer coefficient of the second region A2 is lower than that of the first region A1. The material of the first region A1 is the same as that of the mounting electrodes E1 and E2. The material of the first region A1 and the mounting electrodes E1 and E2 is copper, aluminum, or silver, for example. The material of the second region A2 is, for example, an alloy made of tin as a main component. The alloy made of tin as a main component is an alloy of tin and copper or tin and silver, for example. The second region A2 is formed by, for example, sintering a conductive paste, which is a mixture of metal powder and a resin.

The interlayer connection conductor v1 is provided in the multilayer body 12. In the present example embodiment, the interlayer connection conductor v1 extends through the resin layer 14a in the up-down direction (Z-axis direction). The top end of the interlayer connection conductor v1 contacts the right end portion of the conductive layer 18c. The bottom end of the interlayer connection conductor v1 contacts the left end portion of the inner conductive layer 19c. The structure of the interlayer connection conductor v1 is the same or substantially the same as that of the first interlayer connection conductors V1a and V1b and an explanation thereof will thus be omitted.

The second interlayer connection conductors v2a through v2c are located below the first interlayer connection conductors V1a and V1b (farther toward the negative side of the Z axis than the first interlayer connection conductors V1a and V1b). The second interlayer connection conductors v2a through v2c extend through the resin layer 14b in the up-down direction (Z-axis direction). The top end of the second interlayer connection conductor v2a contacts the left end portion of the inner conductive layer 19a. The top end of the second interlayer connection conductor v2b contacts the right end portion of the inner conductive layer 19b. The top end of the second interlayer connection conductor v2c contacts the right end portion of the inner conductive layer 19c.

The shape of the second interlayer connection conductors v2a through v2c is such that the sectional area of each of the second interlayer connection conductors v2a through v2c in a direction perpendicular or substantially perpendicular to the up-down direction becomes smaller in a direction from bottom to top. More specifically, the second interlayer connection conductors v2a through v2c have a shape of a truncated cone. The area of the top end of each of the second interlayer connection conductors v2a through v2c is smaller than that of the bottom end thereof.

The second interlayer connection conductors v2d through v2f are located below the first interlayer connection conductors V1a and V1b (farther toward the negative side of the Z axis than the first interlayer connection conductors V1a and V1b). The second interlayer connection conductors v2d through v2f extend through the resin layer 14c in the up-down direction (Z-axis direction). The top end of the second interlayer connection conductor v2d contacts the second interlayer connection conductor v2a. The bottom end of the second interlayer connection conductor v2d contacts the inner conductive layer 19d. The top end of the second interlayer connection conductor v2e contacts the second interlayer connection conductor v2b. The bottom end of the second interlayer connection conductor v2e contacts the right end portion of the inner conductive layer 19e. The top end of the second interlayer connection conductor v2f contacts the second interlayer connection conductor v2c. The bottom end of the second interlayer connection conductor v2f contacts the inner conductive layer 19f.

The shape of the second interlayer connection conductors v2d through v2f is such that the sectional area of each of the second interlayer connection conductors v2d through v2f in a direction perpendicular or substantially perpendicular to the up-down direction becomes smaller in a direction from top to bottom. More specifically, the second interlayer connection conductors v2d through v2f have a shape of a truncated cone. The area of the bottom end of each of the second interlayer connection conductors v2d through v2f is smaller than that of the top end thereof.

The Young's modulus of the second interlayer connection conductors v2a through v2f is lower than that of the first region A1 and is equal to that of the second region A2. The material of the second interlayer connection conductors v2a through v2f is, for example, an alloy made of tin as a main component. The alloy made of tin as a main component is an alloy of tin and copper or tin and silver, for example. The second interlayer connection conductors v2a through v2f are formed by, for example, sintering a conductive paste, which is a mixture of metal powder and a resin.

The interlayer connection conductors v3a through v3c are provided in the multilayer body 12. In the present example embodiment, the interlayer connection conductors v3a through v3c extend through the resin layer 14d in the up-down direction. The top end of the interlayer connection conductor v3a contacts the inner conductive layer 19d. The bottom end of the interlayer connection conductor v3a contacts the conductive layer 20a. The top end of the interlayer connection conductor v3b contacts the left end portion of the inner conductive layer 19e. The bottom end of the interlayer connection conductor v3b contacts the conductive layer 20b. The top end of the interlayer connection conductor v3c contacts the inner conductive layer 19f. The bottom end of the interlayer connection conductor v3c contacts the conductive layer 20c.

The shape of the interlayer connection conductors v3a through v3c is such that the sectional area of each of the interlayer connection conductors v3a through v3c in a direction perpendicular to the up-down direction becomes smaller in a direction from top to bottom. More specifically, the interlayer connection conductors v3a through v3c have a shape of a truncated cone. The area of the bottom end of each of the interlayer connection conductors v3a through v3c is smaller than that of the top end thereof.

The interlayer connection conductors v3a and v3c each include a first region A1 and a second region A2. The second region A2 is positioned above the first region A1. The structures of the first region A1 and the second region A2 of the interlayer connection conductors v3a and v3c are the same or substantially the same as those of the first interlayer connection conductors Via and V1b, and an explanation thereof will thus be omitted.

In a forming step of the first interlayer connection conductors Via and V1b and the interlayer connection conductors v1 and v3a through v3c, for example, through-holes are formed to extend through the resin layers 14a and 14d in the up-down direction (Z-axis direction), and then, the through-holes are plated. As a result, the first regions A1 are formed. After the first regions A1 are formed, a conductive paste is filled into the through-holes and is solidified by heat. As a result, the second regions A2 are formed.

The product 100 is mounted on the mounting electrodes E1 through E3 of the circuit substrate 11. The product 100 is a device that generates heat when being operated. The product 100 is an IC (Integrated Circuit), for example. The product 100 is a RFIC (Radio Frequency Integrated Circuit), a CPU (Central Processing Unit), or a power IC, for example. The product 100 includes a body 102 and connectors B1 through B3. The body 102 has a cuboid or substantially cuboid shape. The connectors B1 through B3 are disposed on the bottom surface of the body 102 and are arranged from left to right in this order. The connectors B1 through B3 are solid-phase bonded to the mounting electrodes E1 through E3, respectively. Solid-phase bonding is to form boundaries between the connectors B1 through B3 and the mounting electrodes E1 through E3 through contact of the solid phases of the connectors B1 through B3 and those of the mounting electrodes E1 through E3. In solid-phase bonding, two metals are bonded to each other without a low melting point metal interposed therebetween.

The above-described connectors B1 through B3 are gold bumps, for example. The material for the surface of the connectors B1 through B3 is, for example, thus gold. In the present example embodiment, the entirety or substantially the entirety of the connectors B1 through B3 is made of gold, for example. The connectors B1 through B3 are respectively bonded to the mounting electrodes E1 through E3 by, for example, an ultrasonic bonding technology. During ultrasonic bonding, for example, a portion of gold forming the connectors B1 through B3 and a portion of gold forming the mounting electrodes E1 through E3 are melted and are then solidified. The connectors B1 through B3 are bonded to the mounting electrodes E1 through E3 in this manner.

### Advantageous Effects

(a) In the circuit module 10, it is possible to reduce or prevent damage to the connecting portion between the first interlayer connection conductor V1a and the inner conductive layer 19a. This will be explained more specifically. The material for the surface of the connector B1 is gold, for example. The connector B1 is bonded to the mounting electrode E1 by, for example, the ultrasonic bonding technology. To firmly bond the connector B1 to the mounting electrode E1, the mounting electrode E1 is to be supported by the first interlayer connection conductor V1a having a high stiffness. In one example, the material of the first interlayer connection conductor V1a is the same as that of the mounting electrode E1. This makes it possible to efficiently transmit ultrasonic vibrations to the connector B1 and the mounting electrode E1. As a result, the connector B1 can be firmly bonded to the mounting electrode E1.

However, if the first interlayer connection conductor V1a is too stiff, the connecting portion between the first interlayer connection conductor V1a and the inner conductive layer 19a may be damaged. This will be explained more specifically. The top end of the first interlayer connection conductor V1a contacts the mounting electrode E1, while the bottom end thereof contacts the inner conductive layer 19a. Ultrasonic vibrations are thus transmitted to the first interlayer connection conductor V1a and the inner conductive layer 19a via the mounting electrode E1. If the first interlayer connection conductor V1a is too stiff, ultrasonic vibrations are likely to be applied to the bonding portion between the first interlayer connection conductor V1a and the inner conductive layer 19a.

The first interlayer connection conductor V1a includes the first region A1 and the second region A2. The first region A1 and the second region A2 are arranged in the downward direction in this order. The Young's modulus of the second region A2 is lower than that of the first region A1. The mounting electrode E1 is supported by the first region A1 having a higher stiffness. The connector B1 is thus firmly bonded to the mounting electrode E1. Meanwhile, the second region A2 having a lower stiffness is positioned between the mounting electrode E1 and the inner conductive layer 19a. This makes it difficult to transmit ultrasonic vibrations from the first interlayer connection conductor V1a to the inner conductive layer 19a. Thus, in the circuit module 10, the connecting portion between the first interlayer connection conductor V1a and the inner conductive layer 19a is less likely to be damaged. For the same or similar reason, in the circuit module 10, damage to the connecting portion between the first interlayer connection conductor V1b and the inner conductive layer 19b can be reduced.

(b) In the circuit module 10, the volume of the first region A1 is, for example, about 30% or higher of that of the first interlayer connection conductor V1a. This makes the first interlayer connection conductor V1a stiff, so that the mounting electrode E1 can be supported by the first interlayer connection conductor V1a having a high stiffness. This can efficiently transmit ultrasonic vibrations to the connector B1 and the mounting electrode E1. As a result, the connector B1 can be firmly bonded to the mounting electrode E1.

(c) In the circuit module 10, ultrasonic vibrations are less likely to be transmitted to the inside of the multilayer body 12. This will be explained more specifically. The second interlayer connection conductors v2a through v2f are positioned below the first interlayer connection conductors V1a and V1b (farther toward the negative side of the Z axis than the first interlayer connection conductors V1a and V1b). The Young's modulus of the second interlayer connection conductors v2a through v2f is lower than that of the first region A1. This makes it difficult to transmit ultrasonic vibrations inside the multilayer body 12 via the second interlayer connection conductors v2a through v2f. Ultrasonic vibrations are thus less likely to be transmitted within the multilayer body 12. This reduces the occurrence of electrical disconnection in the multilayer body 12 of the circuit module 10.

(d) In the circuit module 10, the occurrence of warpage in the circuit substrate 11 is reduced. This will be explained more specifically. The first interlayer connection conductors V1a and V1b and the interlayer connection conductor v1 extend through the resin layer 14a in the up-down direction. The interlayer connection conductors v3a through v3c extend through the resin layer 14d in the up-down direction. The first interlayer connection conductors V1a and V1b and the interlayer connection conductors v1 and v3a through v3c each include the first region A1 and the second region A2. With this configuration, the circuit substrate 11 has a symmetrical or substantially symmetrical structure in the up-down direction. The coefficient of linear expansion of and near the top main surface of the circuit substrate 11 is close to that of and near the bottom main surface of the circuit substrate 11. This can lower the occurrence of warpage in the circuit substrate 11 of the circuit module 10.

(e) In the circuit module 10, the material of the resin layers 14a through 14d is a thermoplastic resin. By thermally pressure-bonding the resin layers 14a through 14d with each other, the multilayer body 12 can be formed. During thermal pressure-bonding, the second regions A2 of the first interlayer connection conductors V1a and V1b, the second regions A2 of the interlayer connection conductors v1 and v3a through v3c, and the second interlayer connection conductors v2a through v2f can be hardened.

### First Modified Example

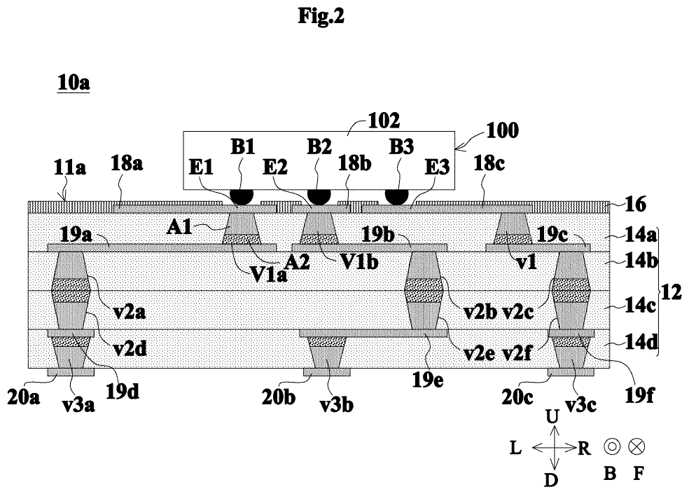

The structure of a circuit module 10a according to a first modified example of an example embodiment of the present invention will be described below with reference to the drawings. FIG. 2 is a sectional view of the circuit module 10a.

The circuit module 10a is different from the circuit module 10 in the structure of the second interlayer connection conductors v2a through v2f. This will be explained more specifically. The second interlayer connection conductors v2a through v2f each include the first region A1 and the second region A2. In the second interlayer connection conductors v2a through v2c, the first region A1 is positioned above the second region A2. In the second interlayer connection conductors v2d through v2f, the second region A2 is positioned above the first region A1. The structure of the other portions of the circuit module 10a is the same as that of the circuit module 10 and an explanation thereof will thus be omitted. The circuit module 10a can achieve the above-described advantageous effects (a), (b), (d), and (e).

(f) In the circuit module 10a, the second interlayer connection conductors v2a through v2f become stiff, which makes a circuit substrate 11a stiff. This makes it easy to transmit ultrasonic vibrations within the circuit substrate 11a. The connectors B1 through B3 can thus be firmly bonded to the mounting electrodes E1 through E3, respectively.

(g) In the circuit module 10a, the first interlayer connection conductors V1a and V1b, the interlayer connection conductors v1 and v3a through v3c, and the second interlayer connection conductors v2a through v2f all include the first region A1 and the second region A2. As a result, the first interlayer connection conductors V1a and V1b, the interlayer connection conductors v1 and v3a through v3c, and the second interlayer connection conductors v2a through v2f can be formed by the same process.

### Second Modified Example

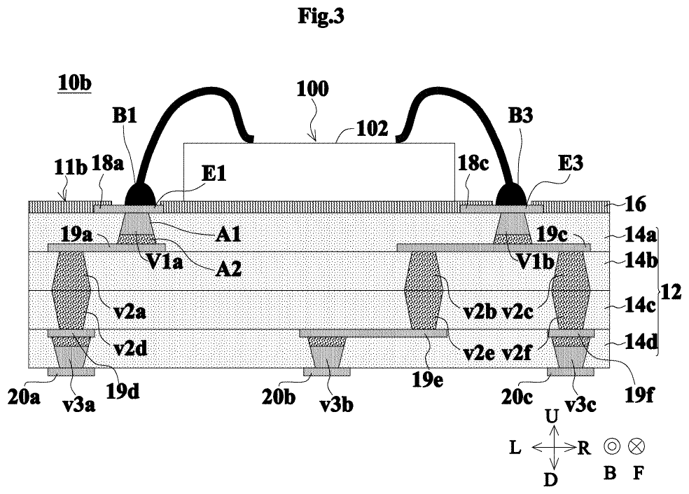

The structure of a circuit module 10b according to a second modified example of an example embodiment of the present invention will be described below with reference to the drawing. FIG. 3 is a sectional view of the circuit module 10b.

The circuit module 10b is different from the circuit module 10 in the structure of the product 100. More specifically, the connectors B1 and B3 are, for example, gold wires. The structure of the other portions of the circuit module 10b is the same or substantially the same as that of the circuit module 10 and an explanation thereof will thus be omitted. The circuit module 10b can achieve the above-described advantageous effects (a) through (e). When connecting the connectors B1 and B3 to the mounting electrodes E1 and E3, respectively, the connector B1 is first connected to the mounting electrode E1 by the ultrasonic bonding technology, and then, the connector B3 is connected to the mounting electrode E3 by the ultrasonic bonding technology. Separately connecting the connectors B1 and B3 to the mounting electrodes E1 and E3 at different times in this manner makes it possible to connect the connectors B1 and B3 to the mounting electrodes E1 and E3 with higher reliability.

### Third Modified Example

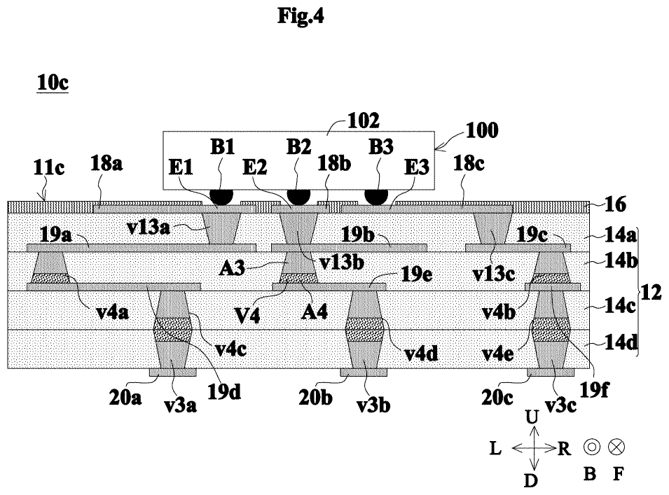

The structure of a circuit module 10c according to a third modified example of an example embodiment of the present invention will be described below with reference to the drawing. FIG. 4 is a sectional view of the circuit module 10c.

The circuit module 10c is different from the circuit module 10 in that it includes third interlayer connection conductors v13a through v13c and a fourth interlayer connection conductor V4. The third interlayer connection conductors v13a through v13c extend through the resin layer 14a in the up-down direction (Z-axis direction). The top end (end of the positive side of the Z axis) of the third interlayer connection conductor v13a contacts the mounting electrode E1, and the bottom end (end of the negative side of the Z axis) thereof contacts the inner conductive layer 19a. The top end (end of the positive side of the Z axis) of the third interlayer connection conductor v13b contacts the mounting electrode E2, and the bottom end (end of the negative side of the Z axis) thereof contacts the inner conductive layer 19b. The top end (end of the positive side of the Z axis) of the third interlayer connection conductor v13c contacts the conductive layer 18c, and the bottom end (end of the negative side of the Z axis) thereof contacts the inner conductive layer 19c.

The shape of the third interlayer connection conductors v13a through v13c is such that the sectional area of each of the third interlayer connection conductors v13a through v13c in a direction perpendicular or substantially perpendicular to the up-down direction becomes smaller in a direction from top to bottom. More specifically, the third interlayer connection conductors v13a through v13c have a shape of a truncated cone. The area of the top end of each of the third interlayer connection conductors v13a through v13c is larger than that of the bottom end thereof.

The Young's modulus of the third interlayer connection conductors v13a through v13c is higher than that of a fourth region A4, which will be described below, and is equal or substantially equal to that of a third region A3, which will be described below. The material of the third interlayer connection conductors v13a through v13c is the same as that of the mounting electrodes E1 through E3. The material of the third interlayer connection conductors v13a through v13c is copper, aluminum, or silver, for example.

The fourth interlayer connection conductor V4 extends through the resin layer 14b in the up-down direction (Z-axis direction). The fourth interlayer connection conductor V4 overlaps the mounting electrode E2 as seen in the up-down direction (Z-axis direction). The top end (end of the positive side of the Z axis) of the fourth interlayer connection conductor V4 contacts the inner conductive layer 19b.

The fourth interlayer connection conductor V4 includes the third region A3 and the fourth region A4 arranged in the up-down direction (Z-axis direction). The fourth region A4 is positioned below the third region A3. The volume of the third region A3 is, for example, about 30% or higher of that of the fourth interlayer connection conductor V4. The Young's modulus of the fourth region A4 is lower than that of the third region A3. The material of the third region A3 is the same as that of the mounting electrodes E1 through E3. The material of the third region A3 and that of the mounting electrodes E1 through E3 are copper, aluminum, or silver, for example. The material of the fourth region A4 is an alloy made of tin as a main component. The alloy made of tin as a main component is an alloy of tin and copper or tin and silver, for example. The fourth region A4 is formed by, for example, sintering a conductive paste, which is a mixture of metal powder and a resin. The structure of the other portions of the circuit module 10c is the same or substantially the same as that of the circuit module 10 and an explanation thereof will thus be omitted. The circuit module 10c can achieve the above-described advantageous effect (b).

In the circuit module 10c, it is possible to reduce damage to the connecting portion between the third interlayer connection conductor v13b and the inner conductive layer 19b. This will be explained more specifically. The material for the surface of the connector B2 is gold, for example. The connector B2 is bonded to the mounting electrode E2 by the ultrasonic bonding technology. To firmly bond the connector B2 to the mounting electrode E2, the mounting electrode E2 is to be supported by the third interlayer connection conductor v13b having a high stiffness. In one example, the material of the third interlayer connection conductor v13b is the same as that of the mounting electrode E2. This makes it possible to efficiently transmit ultrasonic vibrations to the connector B2 and the mounting electrode E2. As a result, the connector B2 can be firmly bonded to the mounting electrode E2.

However, if the third interlayer connection conductor v13b is too stiff, the connecting portion between the third interlayer connection conductor v13b and the inner conductive layer 19b may be damaged. This will be explained more specifically. The top end of the third interlayer connection conductor v13b contacts the mounting electrode E2, while the bottom end thereof contacts the inner conductive layer 19b. Ultrasonic vibrations are thus transmitted to the third interlayer connection conductor v13b and the inner conductive layer 19b via the mounting electrode E2. If the third interlayer connection conductor v13b is too stiff, ultrasonic vibrations are likely to be applied to the bonding portion between the third interlayer connection conductor v13b and the inner conductive layer 19b.

The top end of the fourth interlayer connection conductor V4 contacts the inner conductive layer 19b. The fourth interlayer connection conductor V4 includes the third region A3 and the fourth region A4 arranged in the up-down direction (Z-axis direction). The Young's modulus of the fourth region A4 is lower than that of the third region A3. The inner conductive layer 19b is supported by the fourth interlayer connection conductor V4 including the fourth region A4 having a lower stiffness. When ultrasonic vibrations are applied to the third interlayer connection conductor v13b and the inner conductive layer 19b, the fourth region A4 absorbs ultrasonic vibrations. This makes it less likely to apply force to the connecting portion between the third interlayer connection conductor v13b and the inner conductive layer 19b. Thus, in the circuit module 10c, it is possible to reduce damage to the connecting portion between the third interlayer connection conductor v13b and the inner conductive layer 19b.

In a forming step of the fourth interlayer connection conductor V4, a through-hole is formed to extend through the resin layer 14b in the up-down direction (Z-axis direction), and then, the through-hole is plated. As a result, the third region A3 is formed. After the third region A3 is formed, a conductive paste is filled into the through-hole and is solidified by heat. As a result, the fourth region A4 is formed.

### Other Example Embodiments

A circuit module according to the present invention is not limited to the circuit modules 10 and 10a through 10c and may be modified within the scope and spirit of the present invention. The structures of the circuit modules 10 and 10a through 10c may be combined in a desired manner.

The product 100 is not limited to an electronic component. The product 100 may be a circuit substrate, for example. In this case, the connectors B1 through B3 are mounting electrodes of the circuit substrate. Gold is used for the surface of the connectors B1 through B3, for example.

The material for the surface of the connectors B1 through B3 may be a material other than gold, such as aluminum or silver, for example.

The material of the first region A1 may be different from that of the mounting electrodes E1 through E3.

The circuit substrate may also include a protection layer that covers the bottom main surface of the multilayer body 12.

The material of the conductive layers 18a through 18c and 20a through 20c, the material of the inner conductive layers 19a through 19f, and the material of the first region A1 and that for the third region A3 may be, for example, aluminum or silver.

The fourth region A4 may be located above the third region A3.

The first region A1 and the second region A2 are arranged in the downward direction in this order. This means that the first region A1 is positioned above the second region A2. Alternatively, this means that at least a portion of the second region A2 is positioned below the first region A1. If at least a portion of the second region A2 is positioned below the first region A1, the first region A1 and the second region A2 may contact the conductive layers 18a and 18b. In this case, the area of the first region A1 that contacts the conductive layers 18a and 18b is larger than or equal to that of the second region A2 that contacts the conductive layers 18a and 18b.

The bottom main surface of the conductive layer 18a has a uniform structure. “Uniform structure” means having a planar shape or a shape having projections and recesses in a regular pattern. The boundary between the first region A1 and the conductive layer 18a is the bottom main surface of the conductive layer 18a having this uniform structure. Because of the projections and recesses on the bottom main surface of the conductive layer 18a, the conductive layer 18a includes portions projecting downward from the bottom main surface of the conductive layer 18a, and these portions are not a portion of the first region A1, but are part of the conductive layer 18a.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit module comprising:
a circuit substrate; and
a product; wherein
the circuit substrate includes:
a multilayer body including a plurality of resin layers stacked on each other in a direction of a Z axis, each of the plurality of the resin layers including a positive main surface positioned on a positive side of the Z axis;
a mounting electrode on the positive main surface of a resin layer which is positioned farther toward the positive side of the Z axis than other resin layers of the plurality of resin layers;
an inner conductive layer provided in the multilayer body and overlapping the mounting electrode as seen in the direction of the Z axis; and
a first interlayer connection conductor extending through a resin layer of the plurality of the resin layers in the direction of the Z axis, an end of the first interlayer connection conductor on the positive side of the Z axis contacts the mounting electrode, and an end of the first interlayer connection conductor on a negative side of the Z axis contacts the inner conductive layer;
the product includes:
a connector solid-phase bonded to the mounting electrode;
the first interlayer connection conductor includes a first region and a second region;
the first region and the second region are sequentially provided in a direction toward the negative side of the Z axis in order of the first region and the second region;
the mounting electrode is in contact with the first region; and
a Young's modulus of the second region is lower than a Young's modulus of the first region.

2. The circuit module according to claim 1, wherein a volume of the first region is about 30% or higher of a volume of the first interlayer connection conductor.

3. The circuit module according to claim 1, wherein a material of the first region is the same as a material of the mounting electrode.

4. The circuit module according to claim 3, wherein the material of the first region and the material of the mounting electrode are copper, aluminum, or silver.

5. The circuit module according to claim 1, wherein a material of the second region is an alloy including tin as a main component.

6. The circuit module according to claim 1, wherein
the circuit substrate includes a second interlayer connection conductor positioned farther toward the negative side of the Z axis than the first interlayer connection conductor and extends through a resin layer of the plurality of the resin layers in the direction of the Z axis; and
a Young's modulus of the second interlayer connection conductor is lower than the Young's modulus of the first region.

7. The circuit module according to claim 6, wherein a material of the second interlayer connection conductor is an alloy including tin as a main component.

8. The circuit module according to claim 1, wherein the circuit substrate includes a protection layer covering the positive main surface of the resin layer positioned farther toward the positive side of the Z axis than the other resin layers.

9. The circuit module according to claim 1, wherein a material of the plurality of resin layers is a thermoplastic resin.

10. The circuit module according to claim 1, wherein a material for a surface of the connector is gold.

11. The circuit module according to claim 1, wherein a Young's modulus of a lower half of the first interlayer connection conductor is different from a Young's modulus of an upper half of the first interlayer connection conductor.

12. The circuit module according to claim 1, wherein the first interlayer connection conductor has a truncated cone shape.

13. A manufacturing method for the circuit module according to claim 1, the manufacturing method comprising:
in a forming step of the first interlayer connection conductor:
forming the first region by forming a through-hole extending through a resin layer of the plurality of the resin layers in the direction of the Z axis and by plating the through-hole; and
after the first region is formed, forming the second region by filling a conductive paste into the through-hole; and
bonding the connector to the mounting electrode using an ultrasonic bonding technology.

14. A circuit module comprising:
a circuit substrate; and
a product; wherein
the circuit substrate includes:
a multilayer body including a plurality of resin layers stacked on each other in a direction of a Z axis, each of the plurality of the resin layers including a positive main surface positioned on a positive side of the Z axis;
a mounting electrode on the positive main surface of a resin layer which is positioned farther toward the positive side of the Z axis than other resin layers of the plurality of resin layers;
an inner conductive layer provided in the multilayer body and overlapping the mounting electrode as seen in the direction of the Z axis;
a third interlayer connection conductor extending through a resin layer of the plurality of the resin layers in the direction of the Z axis, and an end of the third interlayer connection conductor on the positive side of the Z axis contacts the mounting electrode, while an end of the third interlayer connection conductor on a negative side of the Z axis contacts the inner conductive layer; and
a fourth interlayer connection conductor extending through a resin layer of the plurality of the resin layers in the direction of the Z axis and overlapping the mounting electrode as seen in the direction of the Z axis, and an end of the fourth interlayer connection conductor on the positive side of the Z axis contacts the inner conductive layer;
the product includes:
a connector solid-phase bonded to the mounting electrode;
the fourth interlayer connection conductor includes a third region and a fourth region, the third region and the fourth region being provided in the direction of the Z axis,
a material of the third interlayer connection conductor and a material of the third region are the same as a material of the mounting electrode;
the inner conductive layer is in contact with the third region; and
a Young's modulus of the fourth region is lower than a Young's modulus of the third region.

15. The circuit module according to claim 14, wherein a volume of the third region is about 30% or higher of a volume of the fourth interlayer connection conductor.

16. The circuit module according to claim 14, wherein a material of the third region is the same as a material of the mounting electrode.

17. The circuit module according to claim 16, wherein the material of the first region and the material of the mounting electrode are copper, aluminum, or silver.

18. The circuit module according to claim 1, wherein a material of the fourth region is an alloy including tin as a main component.

19. A manufacturing method for the circuit module according to claim 14, the manufacturing method comprising:
in a forming step of the fourth interlayer connection conductor:
forming the third region by forming a through-hole extending through a resin layer of the plurality of the resin layers in the direction of the Z axis and by plating the through-hole; and
after the third region is formed, forming the fourth region by filling a conductive paste into the through-hole; and
in a step of bonding the connector to the mounting electrode:
bonding the connector to the mounting electrode by using an ultrasonic bonding technology.
